(19) United States
(12) Patent Application Publication
(10) Pub. No.: US 2025/0355025 A1
(43) Pub. Date: Nov. 20, 2025

(54) CURRENT SENSOR SYSTEMS

(71) Applicant: Allegro MicroSystems, LLC, Manchester, NH (US)

(72) Inventors: Emil Pavlov, Heidelberg (DE); Simon E. Rock, Heidelberg (DE)

(73) Assignee: Allegro MicroSystems, LLC, Manchester, NH (US)

(21) Appl. No.: 18/663,263

(22) Filed: May 14, 2024

(51) Int. Cl. G01R 15/20; G01R 19/00; G01R 19/10

(52) U.S. Cl. CPC G01R 15/207; G01R 19/0023; G01R 19/10

(57) ABSTRACT

Provided are compact current sensing systems based on printed circuit boards (PCB) and/or integrated circuits (IC). Sensors are configured to detect or sense a current, such as a leakage current. Semiconductor die supporting magnetic field sensing elements are placed equidistantly and symmetrically from one or more conductors to sense a current in the conductor. A circuit may output a signal based on a difference between the outputs of the sensing elements.

### FIELD OF TECHNOLOGY

The described technology generally relates to current sensor systems, more particularly to open and closed-loop current sensors and leakage current sensors implemented in printed circuit boards and/or integrated circuit packages.

### BACKGROUND

Leakage current sensing is central to the safety of many systems. In many applications, however, the specificity with which currents must be sensed poses a significant technological challenge. For example, leakage current sensors or detectors may be required to measure a difference of less than 0.5% between an input and an output current. Additionally, systems including solar energy applications are dependent on leakage current sensors due to rigorous regulation requirements. Such sensors are required to detect leakage currents of up to about 5-10 mA. Traditional leakage current sensors are also both bulky and expensive.

### SUMMARY

Aspects of the present disclosure relate to compact current sensing systems based on printed circuit boards (PCB), and/or integrated circuits (IC). The sensors may be configured to detect or sense a current, such as a leakage current. Semiconductor die supporting magnetic field sensing elements may be placed equidistantly and symmetrically from one or more conductors to sense currents in the conductors. A circuit may output a signal based on a difference between the outputs of the sensing elements.

According to one aspect, a current sensing system may include a first semiconductor die supporting a first magnetic field sensing element. The first magnetic field sensing element may be configured to sense a first magnetic field associated with a first current through a first conductor and a second magnetic field associated with a second current through a second conductor. The first magnetic field sensing element may be further configured to generate a first output signal indicative of the first current and second current. The first magnetic field sensing element may be disposed a first distance from the first conductor and a second distance from the second conductor. A second semiconductor die may support a second magnetic field sensing element. The second magnetic field sensing element may be configured to sense the first magnetic field and the second magnetic field. The second magnetic field sensing element may be further configured to generate a second output signal indicative of the first current and second current. The second magnetic field sensing element may be disposed a third distance substantially equal to the first distance from the second conductor and a fourth distance substantially equal to the second distance from the first conductor. A circuit may be responsive to the first output signal from the first magnetic field sensing element and the second output signal from the second magnetic field sensing element. The circuit may be configured to generate a current sensor output signal based on a difference between the first output signal and the second output signal.

The current sensing system may include, alone or in combination, one or more of the following features. The current sensor output signal may be indicative of a difference between the first current and the second current. The first conductor and the second conductor may comprise busbars. A substrate may be adjacent to the first magnetic field sensing element and the second magnetic field sensing element. The substrate may be a printed circuit board (PCB). The first conductor and the second conductor may comprise conductive traces. The substrate may be a lead frame. The first current may flow in an opposite direction from the second current. The circuit may comprise a differential operational amplifier. A first compensation coil may be proximate to the first magnetic field sensing element and a second compensation coil may be proximate to the second magnetic field sensing element. The first compensation coil may be located in the first semiconductor die and the second compensation coil may be located in the second semiconductor die. The first compensation coil and the second compensation coil may be located on a substrate supporting the first semiconductor die and the second compensation coil. The first and second magnetic field sensing elements may comprise one or more magnetoresistive elements or Hall effect elements. The first conductor may be disposed vertically to the second conductor and symmetrically to first magnetic sensing element and the second magnetic sensing element. The first conductor may be disposed horizontally to the second conductor.

According to another aspect, a method of sensing a current through one or more conductors may include providing a first semiconductor die supporting a first magnetic field sensing element. The first magnetic field sensing element may be configured to sense a first magnetic field associated with a first current through a first conductor and a second magnetic field associated with a second current through a second conductor. The first magnetic field sensing element may be further configured to generate a first output signal indicative of the first current and second current. The first magnetic field sensing element may be positioned a first distance from the first conductor and a second distance from the second conductor. A second semiconductor die supporting a second magnetic field sensing element may be provided. The second magnetic field sensing element may be configured to sense the first magnetic field and the second magnetic field. The second magnetic field sensing element may be further configured to generate a second output signal indicative of the first current and second current. The second magnetic field sensing element may be positioned a third distance substantially equal to the first distance from the second conductor and a fourth distance substantially equal to the second distance from the first conductor. A circuit responsive to the first output signal from the first magnetic field sensing element and the second output signal from the second magnetic field sensing element may be provided. The circuit may be configured to generate a current sensor output signal based on a difference between the first output signal and the second output signal.

The method may include, alone or in combination, one or more of the following features. The current sensor output signal may be indicative of a difference between the first current and the second current. The first conductor and the second conductor may comprise busbars. A substrate may be provided adjacent to the first magnetic field sensing element and the second magnetic field sensing element. The substrate may be a PCB. The first conductor and the second conductor may comprise conductive traces. The substrate may be a lead frame. The first current may flow in an opposite direction from the second current. The circuit may comprise a differential operational amplifier. A first compensation coil may be provided proximate to the first magnetic field sensing element and a second compensation coil may be provided proximate to the second magnetic field sensing element. The first compensation coil may be located in the first semiconductor die and the second compensation coil may be located in the second semiconductor die. The first compensation coil and the second compensation coil may be located on a substrate supporting the first semiconductor die and the second compensation coil. The first and second magnetic field sensing elements may comprise one or more magnetoresistive elements or Hall effect elements. The first conductor may be disposed vertically to the second conductor and symmetrically to first magnetic sensing element and the second magnetic sensing element. The first conductor may be disposed horizontally to the second conductor.

According to another aspect, a current sensing system may include a first semiconductor die supporting a first magnetic field sensing element. The first magnetic field sensing element may be configured to sense a first magnetic field associated with a current through a conductor and generate a first output signal indicative of the current. The first magnetic field sensing element may be disposed a first distance from the conductor. A first compensation coil may be proximate to the first magnetic field sensing element. A second semiconductor die may support a second magnetic field sensing element. The second magnetic field sensing element may be configured to sense a second magnetic field associated with the current through the conductor and generate a second output signal indicative of the current. The second magnetic field sensing element may be disposed a second distance from the conductor equal to the first distance. A second compensation coil may be proximate to the second magnetic field sensing element. A circuit may be responsive to the first output signal from the first magnetic field sensing element and the second output signal from the second magnetic field sensing element. The circuit may be configured to generate a current sensor output signal based on a difference between the first output signal and the second output signal.

The current sensing system may include, alone or in combination, one or more of the following features. A substrate may be adjacent to the first magnetic field sensing element and the second magnetic field sensing element. The substrate may be a PCB. The substrate may be a lead frame. The first compensation coil may be located in the first semiconductor die and the second compensation coil is located in the second semiconductor die. The first compensation coil and the second compensation coil may be located on a substrate supporting the first semiconductor die and the second compensation coil. The first and second magnetic field sensing elements may comprise one or more magnetoresistive elements or Hall effect elements.

### BRIEF DESCRIPTION OF THE DRAWINGS

The foregoing features of the disclosure, as well as the disclosure itself may be more fully understood from the following detailed description of the drawings. The drawings aid in explaining and understanding the disclosed technology. Since it is often impractical or impossible to illustrate and describe every possible embodiment, the provided figures depict one or more exemplary embodiments. Accordingly, the figures are not intended to limit the scope of the invention. Like numbers in the figures denote like elements.

FIG. 1A is a block diagram of a leakage current sensor system, according to aspects of the present disclosure;

FIG. 1B is a cross-sectional side view of the leakage current sensor system of FIG. 1A, according to aspects of the present disclosure;

FIG. 2A is a block diagram of a leakage current sensor system, according to aspects of the present disclosure;

FIG. 2B is a cross-sectional side view of the leakage current sensor system of FIG. 2A, according to aspects of the present disclosure;

FIG. 3A is a block diagram of a leakage current sensor system, according to aspects of the present disclosure;

FIG. 3B is a cross-sectional side view of the leakage current sensor system of FIG. 3A, according to aspects of the present disclosure;

FIG. 4A is a block diagram of a current sensor system, according to aspects of the present disclosure;

FIG. 4B is a cross-sectional side view of the current sensor system of FIG. 4A, according to aspects of the present disclosure;

FIG. 5A is a block diagram of a current sensor system, according to aspects of the present disclosure;

FIG. 5B is a cross-sectional side view of the current sensor system of FIG. 5A, according to aspects of the present disclosure;

FIG. 6 is a side view of a leakage current sensor system, according to aspects of the present disclosure;

FIG. 7 is an exploded view of a current sensor integrated circuit package, according to aspects of the present disclosure;

FIG. 8 is a block diagram showing an example current sensor for a current sensor system, according to aspects of the present disclosure; and

FIG. 9 is a block diagram of a closed-loop current sensor, according to aspects of the present disclosure.

### DETAILED DESCRIPTION

Aspects of the present disclosure relate generally to compact current sensing systems based on printed circuit boards (PCB) and/or integrated circuits (IC). The sensors may be configured to detect or sense a current, such as a leakage current. Semiconductor die supporting magnetic field sensing elements may be placed equidistantly and symmetrically from one or more conductors to sense currents in the conductors. A circuit may output a signal based on a difference between the outputs of the sensing elements.

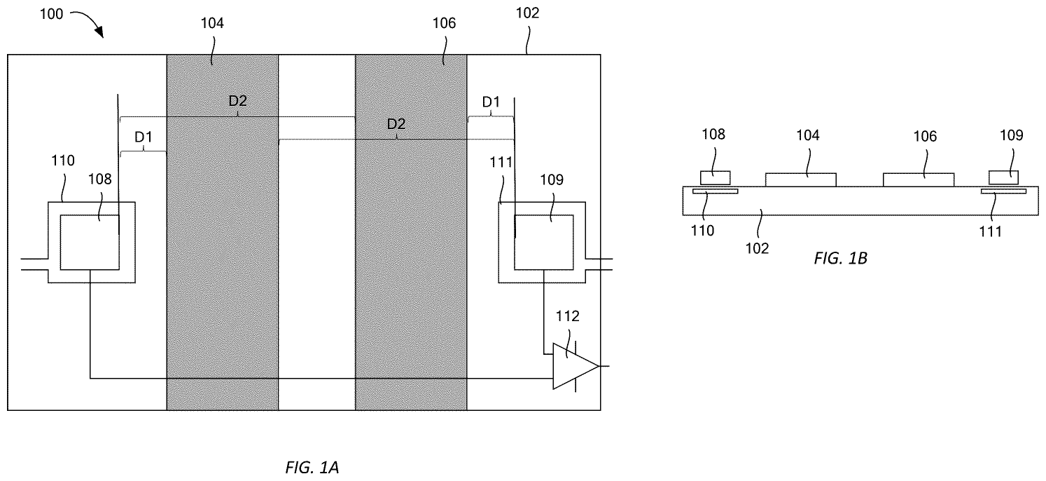

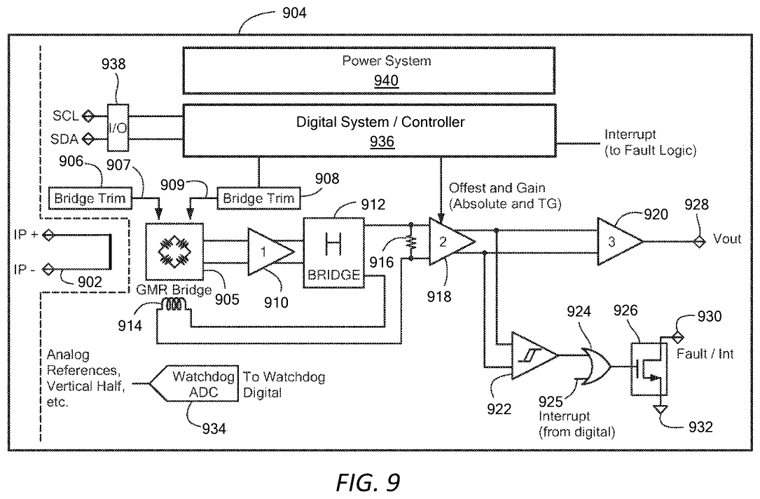

Referring to FIGS. 1A-1B, a leakage current sensor system 100 includes a substrate 102. According to one aspect, the substrate 102 may be a PCB. The substrate 102 may support or include a first conductor 104 and a second conductor 106 configured to carry a first current (e.g. an input current) and second current (e.g., an output current) respectively. According to one or more aspects, the first conductor 104 and the second conductor 106 may be or include busbars, conductive traces, or the like. Two IC packages, such as a first IC package 108 and a second IC package 109, may be disposed adjacent to the substrate 102 (i.e., may be attached to a top surface of the substrate, such as by soldering or with a non-conductive adhesive as non-limiting examples) and symmetrically to each of the first conductor 104 and second conductor 106. Each of the IC packages 108, 109 may include a semiconductor die supporting one or more magnetic field sensing elements configured to sense a magnetic field associated with one or more currents. The IC packages 108, 109 may implement closed-loop current sensing described herein and shown, for example, in FIG. 9. According to one aspect, compensation coils, such as a first coil 110 and a second coil 111 may be disposed adjacent to the first IC package 108 and second IC package 109, respectively. The coils 110, 111 may be disposed proximate to the respective IC package 108, 109 and may be driven in order to apply an equal and opposite magnetic fields with respect to the sensed magnetic fields to the sensing elements in the packages thus driving any sensed magnetic field to zero. According to one aspect, the first coil 110 and the second coil 111 may be integrated into the substrate 102 below the respective IC packages 108, 109. For example, in the case of a PCB substrate 102, the coils 110, 111 can be formed as respective conductive traces.

According to one aspect, the first conductor 104 may carry an input current from an electrical system (not shown). The second conductor 106 may carry an output current. According to one aspect, the input current direction may be opposite to the output current direction. While the first conductor 104 and the second conductor 106 are shown in FIG. 1B as disposed atop the substrate 102 (e.g., in the form of busbars), the conductors may also or instead be integrated in the substrate 102 (e.g., in the form of conductive PCB traces).

The first IC package 108 and the second IC package 109 may be disposed adjacent to the substrate 102 equidistantly and symmetrically on both sides of the respective conductors 104, 106. For example, the first IC package 108 may be disposed at a distance D1 from the first conductor 104 and a distance D2 from the second conductor 106. Likewise, the second IC package 109 may be disposed at the distance D1 from the second conductor 106 and the distance D2 from the first conductor 104.

As the direction of the currents in the first conductor 104 and the second conductor 106 are opposite, the currents may generate magnetic fields in opposite directions at the locations of each of the IC packages 108, 109, respectively. For example, the input current through the first conductor 104 may generate a first magnetic field, F₁. The output current through the second conductor 106 may generate a second magnetic field, F₂. The first IC package 108 may be at a greater distance, D2, to the second conductor 106 compared to the distance, D1, of the second IC package 109, to the second conductor 106. Accordingly, the second IC package 109 may sense the full magnetic field, F₂, and the first IC package 108 may sense an attenuated field, αF₂, where ‘α’ may be an attenuation factor. Similarly, the first IC package 108 may sense the full magnetic field F₁, and the second IC package 109 may sense an attenuated field, αF₁. According to one aspect, because the IC packages 108, 109 are disposed symmetrically with respect to the conductors, the attenuation factor, ‘α’, may be the same for both magnetic fields sensed by the IC packages.

The first IC package 108 and the second IC package 109 may be connected to an output circuit 112. The output circuit 112 may receive output signals from the IC packages 108, 109 indicative of the currents in the first conductor 104 and the second conductor 106, as described herein. The output circuit 112 may be configured to generate a current output signal based on the difference between the input current and the output current as sensed by the first IC package 108 and the second IC package 109. According to one aspect, the output circuit 112 may be or include a differential operational amplifier (op amp).

According to one aspect, the magnetic fields at the IC packages 108, 109 may be described as:

$${S}_{1} = {F}_{1} - α {F}_{2} ;$$

$${S}_{2} = - α {F}_{2} + {F}_{2} ;$$

Where S₁ is the resulting magnetic field at the first IC package 108 and S₂ is the resulting magnetic field at the second IC package 109. It should be appreciated that the sensor outputs of the first and second IC packages 108, & 109 are proportional to the resulting magnetic fields S₁, S₂, respectively. The relationship between the fields, F₁, and F₂, may be written:

$${F}_{2} = {F}_{1} - {F}_{L} ;$$

where F_{L} is the field generated by a leakage current. The resulting magnetic fields from the first IC package 108 and the second IC package 109 may be subtracted using the output circuit 112, e.g., a differential op amp, to generate a current sensor output signal. The current sensor output signal (i.e., the resulting magnetic field from both IC packages 108, 109) may be described as

$$S = {S}_{1} - {S}_{2} = {F}_{1} - α ( {F}_{1} - {F}_{L} ) + α {F}_{1} - ( {F}_{1} - {F}_{L} ) = {F}_{L} ( 1 + α ) .$$

Accordingly, the current sensor output signal, S, may be a signal dependent on the leakage current and the geometrical position of the current sensing IC packages 108, 109 and the two conductors 104, 106. According to one aspect, the attenuation factor, α, may be determined either by simulation or by calibration after installation of the current sensor system in an application system. For example, the magnetic field created by the current flowing in the individual conductors may be simulated to determine the attenuation factor. Furthermore, the signal, S, may be substantially immune to stray magnetic fields (i.e., stray field robust) due to the differential nature of the measurements.

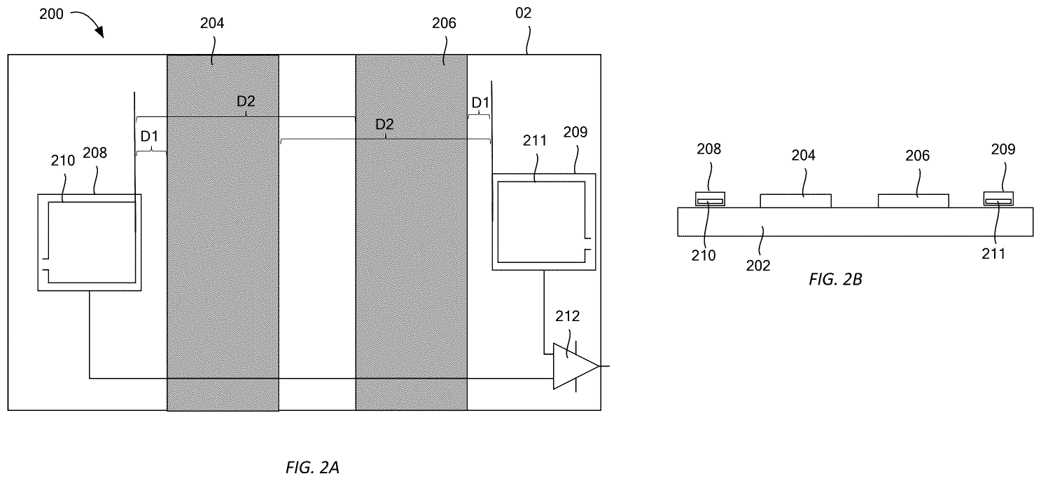

Referring now to FIGS. 2A-2B, an alternatively configured current sensor system 200 may include a substrate 202, a first conductor 204, a second conductor 206, a first IC package 208, a second IC package 209 and a circuit 212 configured to receive output signals from the IC packages. The first IC package 208 and the second IC package 209 may be disposed adjacent to the substrate 202 (i.e., may be attached to a top surface of the substrate, such as by soldering or with a non-conductive adhesive as non-limiting examples) equidistantly and symmetrically on both sides of the conductors. For example, the first IC package 208 may be disposed at a distance D1 from the first conductor 204 and a distance D2 from the second conductor 206. Likewise, the second IC package 209 may be disposed at the distance D1 from the second conductor 206 and the distance D2 from the first conductor 204.

The current sensor system 200 may be operationally similar to the system 100 shown in FIG. 1A, however, according to one aspect, compensation coils providing closed-loop current sensing may be integrated into the semiconductor die of the IC packages 208, 209 rather than being disposed on the substrate. For example, a first coil 210 may be integrated into the first IC package 208 and a second coil 211 may be integrated into the second IC package 209. According to one aspect, the first coil 210 and the second coil 211 may be provided in the form of one or more metal layers of the semiconductor die of the IC packages 208, 209.

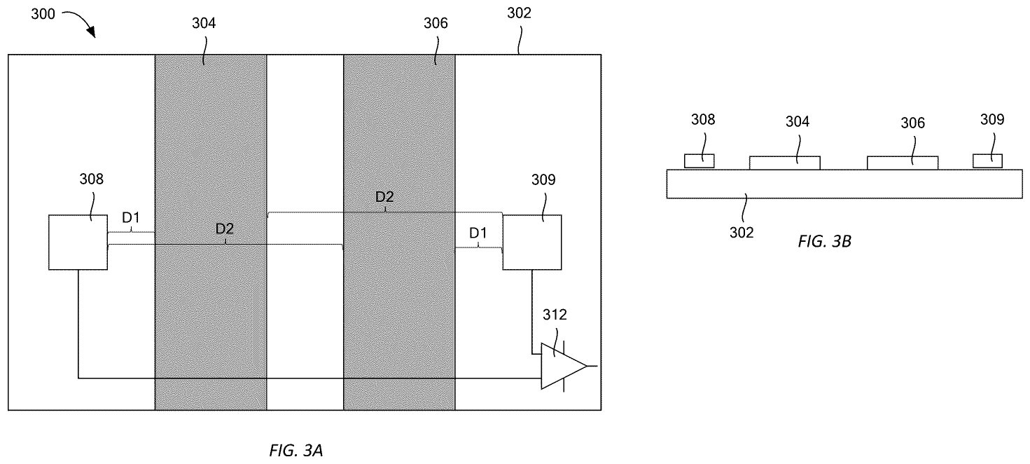

FIGS. 3A-3B are block diagrams of another alternative configuration of a current sensing system 300. The system 300 may include a substrate 302, a first conductor 304, a second conductor 306, a first IC package 308, a second IC package 309 and a circuit 312 configured to receive output signals from the IC packages. The first IC package 308 and the second IC package 309 may be disposed adjacent to the substrate 302 (i.e., may be attached to a top surface of the substrate, such as by soldering or with a non-conductive adhesive as non-limiting examples) equidistantly and symmetrically on both sides of the conductors. For example, the first IC package 308 may be disposed at a distance D1 from the first conductor 304 and a distance D2 from the second conductor 306. Likewise, the second IC package 309 may be disposed at the distance D1 from the second conductor 306 and the distance D2 from the first conductor 304.

The current sensor system 300 may be operationally similar to the system 100 shown in FIG. 1A, however, according to one aspect, the IC packages 308, 309 may provide open loop current sensing rather than the closed-loop sensing previously described (i.e., no compensation coils are provided).

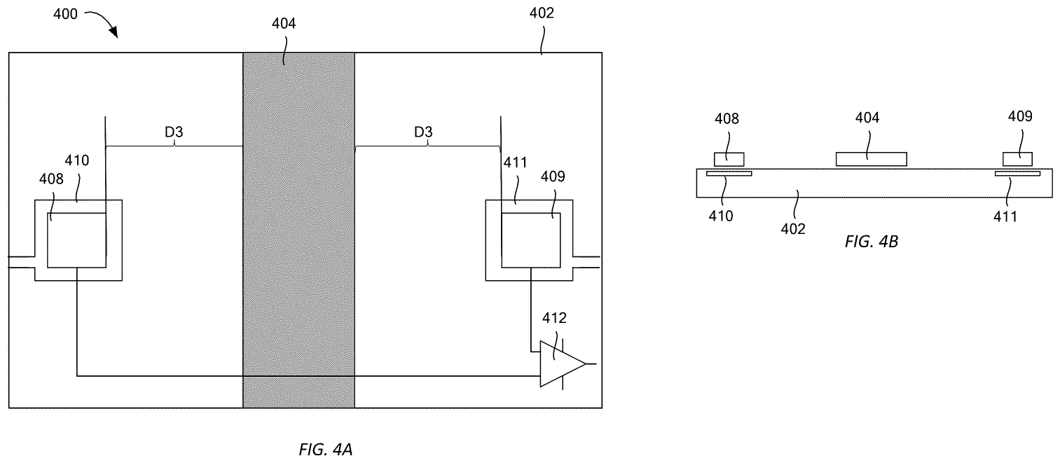

Referring now to FIGS. 4A-4B, a single conductor current sensor system 400 is shown, according to aspects of the present disclosure. A substrate 402 may support a first conductor 404. A first IC package 408 and a second IC package 409 may be disposed equidistantly and symmetrically with respect to the first conductor 404. For example, the first IC package 408 may be disposed at a distance D3 from the first conductor 404. Likewise, the second IC package 409 may be disposed at the distance D3 from the first conductor 406.

The IC packages 408, 409 may be closed-loop current sensor IC packages, described herein and shown, for example, in FIG. 9. According to one aspect, compensation coils, such as a first coil 410 and a second coil 411 may be disposed adjacent to the first IC package 408 and second IC package 409, respectively. According to one aspect, the coils 410, 411 may be integrated into the substrate 402 proximate to the placement of the respective IC packages. For example, in the case of a PCB substrate 402, the coils 410, 411 can be formed as respective conductive traces. The configuration of the IC packages and compensation coils may be substantially similar to those described in connection with FIGS. 1A-1B, above.

In operation, the first conductor 404 may carry a current and the magnetic field sensing elements of the first IC package 408 and the second IC package 409 may sense respective magnetic fields and generate output signals indicative of the current carried in the first conductor. A circuit 412 may receive output signals from the first IC package 408 and the second IC package 409 and generate an output signal based on the difference between the two signals received from the IC packages.

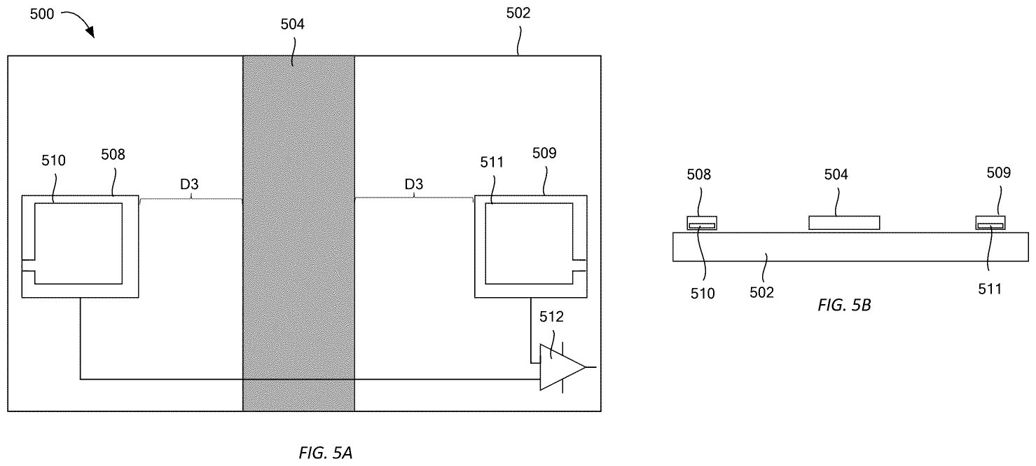

FIGS. 5A-5B are block diagrams of an alternative current sensor system 500. The system 500 may include a substrate 502, a first conductor 504, a first IC package 508, a second IC package 509, and a circuit 512 configured to receive output signals from the IC packages. The first IC package 508 and the second IC package 509 may be disposed adjacent to the substrate 502 (i.e., may be attached to a top surface of the substrate, such as by soldering or with a non-conductive adhesive as non-limiting examples) equidistantly and symmetrically on both sides of the conductors. For example, the first IC package 508 may be disposed at a distance D3 from the first conductor 504. Likewise, the second IC package 509 may be disposed at the distance D3 from the first conductor 504.

The IC packages 508, 509 may be closed-loop current sensor IC packages, described herein and shown, for example, in FIG. 9. According to one aspect, compensation coils, such as a first coil 510 and a second coil 511, may be integrated to the first IC package 508 and second IC package 509, respectively. The configuration of the IC packages and compensation coils may be substantially similar to those described in connection with FIGS. 2A-2B, above. A circuit 512 may receive output signals from the first IC package 508 and the second IC package 509 and generate an output signal based on the difference between the two signals received from the IC packages.

The current sensor system 500 may be operationally similar to the system 400 shown in FIG. 4A, however, the compensation coils providing closed-loop current sensing may be integrated in the IC packages, rather than the substrate 502. For example, a first coil 510 may be integrated into the first IC package 508 and a second coil 511 may be integrated into the second IC package 511. According to one aspect, the first coil 510 and the second coil 511 may be provided in the form of one or more metal layers of the semiconductor die of the IC packages 508, 509.

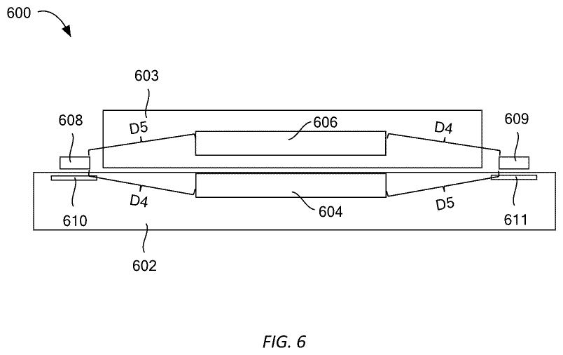

Turning now to FIG. 6, an alternatively configured current sensor system 600 may include a first substrate 602, a second substrate 603, a first conductor 604, a second conductor 606, a first IC package 608, a second IC package 609, and a circuit (not shown) configured to receive output signals from the IC packages. According to one aspect, the first substrate 602 may include or integrate the first conductor 604. The second substrate 603 may include or incorporate the second conductor 606. The first substrate 602 and the second substrate 603 may be positioned such that the first conductor 604 and the second conductor 606 are aligned substantially vertically with respect to each other. According to one aspect, the first substrate 602 and the second substrate 603 may be coupled together using board-to-board connectors, such as pin headers. Alternatively, the first substrate 602 and the second substrate 603 may be coupled by soldering the edges of the substrates 602, 603 together.

The first IC package 608 and the second IC package 609 may be disposed adjacent to the first substrate 602 and the second substrate 603. According to one aspect, the IC packages 608, 609 may be supported by the first substrate 602 (i.e., may be attached to a top surface of the substrate 602, such as by soldering or with a non-conductive adhesive as non-limiting examples). The first substrate 602 may further include a first compensation coil 610 adjacent to the first IC package 608 and a second compensation coil 611 adjacent to the second IC package 609. The compensation coils 610, 611 may be disposed proximate to the respective IC packages 608, 609 in order to apply an equal and opposite magnetic field to the sensing elements in the packages thus driving any differential magnetic field to zero. For example, in the case of a PCB substrate 602, the coils 610, 611 can be formed as respective conductive traces. While the first coil 610 and the second coil 611 may be integrated into the substrate 602 below the respective IC package 608, 609, as shown in FIG. 6, one skilled in the art will recognize that the coils may instead be integrated into the IC packages themselves, as described herein.

According to one aspect, the first IC package 608 and the second IC package 609 are positioned equidistantly and symmetrically on both sides of the conductors. For example, the first IC package 608 may be disposed at a distance D4 from the first conductor 604 and at a distance D5 from the second conductor 606. Likewise, the second IC package 609 may be disposed at the distance D4 from the second conductor 606 and the distance D5 from the first conductor 604. According to one aspect, the distances D4 and D5 may be substantially equal.

The current sensor system 600 may be operationally similar to the system 100 shown in FIG. 1A, however, the first conductor 604 and the second conductor 606 may be vertically aligned and integrated into the first substrate 602 and second substrate 603, respectively, as shown. A first current may flow through the first conductor 604 in a first direction (e.g., as shown in FIG. 6, into the page) while a second current may flow through the second conductor 606 in a second direction, opposite to the first current (e.g., as shown in FIG. 6, out of the page). Accordingly, the currents may generate magnetic fields in opposite directions at the locations of each of the IC packages. As described herein, each IC package may sense both fields and a differential op amp may receive signals indicative of the respective currents and generate an output signal based on the difference in the signals received from the IC packages.

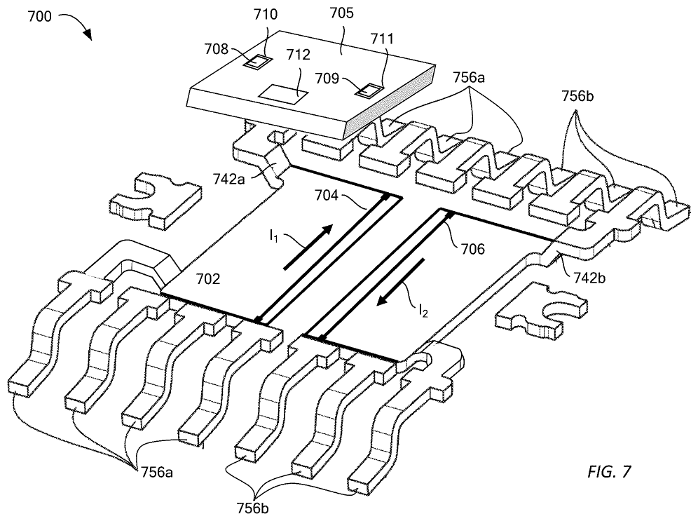

Turning now to FIG. 7, a current sensor IC package 700 is shown according to aspects of the present disclosure. Operationally, the current sensor IC package 700 may function substantially similarly to the substrate-based current sensor systems described herein, such as current sensor system 100 (FIGS. 1A-1B). The current sensor IC package 700, however, may be embodied or implemented in an IC package, rather than on a PCB-based substrate or the like. Accordingly, the current sensor IC package 700 may include a lead frame 702, leads, generally labelled 756, and a semiconductor die 705.

According to one aspect, the lead frame 702 may include or form one or more conductors, such as a first conductor 704 and a second conductor 706. While the first conductor 704 and the second conductor 706 are shown as components on the lead frame, they may instead be formed in or integrated into the body of lead frame 702. Leads 756 may include a first plurality of leads 756a connected the first conductor 704, through for example connect member 742a, and a second plurality of leads 756b connected to the second conductor 706 through for example connect member 742b. The first plurality of leads 756a and the first conductor 704 may carry a first current, I₁. The second plurality of leads 756b and the second conductor 706 may carry a second current, I₂. According to one aspect, I₁ may be an input current while I₂ may be an output current.

The semiconductor die 705 may include one or more magnetic field sensing elements, such as a first magnetic field sensing element 708 and a second magnetic field sensing element 709. According to one aspect, the first conductor 704 and the second conductor 706 may be connected to a subset of the leads 756, leaving another subset of leads 756 to connect to the semiconductor die 705. Alternatively, the package 700 may include leads on all four sides in which leads 756 on two sides are connected to the first and second conductors 704, 706 and leads 756 on the other two sides are connected to the semiconductor die 705. The semiconductor die 705 may be positioned with respect to the lead frame 702 such that the first magnetic field sensing element 708 and the second magnetic field sensing element 709 are adjacent to the lead frame 702 and equidistant and symmetric with respect to both the first conductor 704 and the second conductor 706. For example, the first magnetic field sensing element 708 may be at a first distance from the first conductor 704 and a second distance from the second conductor 706. Likewise, the second magnetic field sensing element 709 may be at the first distance from the second conductor 706 and the second distance from the first conductor 704. Like the current sensing system shown in FIGS. 1A-1B, and described above, the magnetic field sensing elements may measure the magnetic fields generated by current through the conductors.

The semiconductor die 705 may further include an output circuit 712 connected to the first magnetic sensing element 708 and the second magnetic field sensing element 709. The output circuit 712 may receive output signals from the respective sensing elements indicative of the currents in the first conductor 704 and the second conductor 706, as described herein. The output circuit 712 may be configured to generate a current sensor output signal based on the difference between the input current and the output current as sensed by the first magnetic field sensing element 708 and the second magnetic field sensing element 709. According to one aspect, the output circuit 712 may be or include a differential op amp. Accordingly, the current sensor output signal may be a signal indicative of the leakage current based in part on the position of the magnetic field sensing elements 708, 709 with respect to the conductors 704, 706.

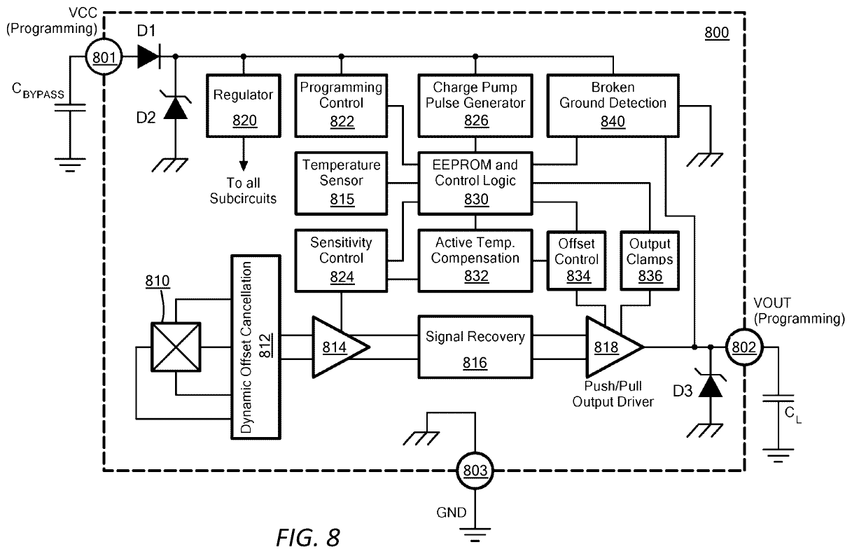

FIG. 8 is a block diagram showing an example current sensor 800, according to the one aspect. The example current sensor 800 includes, for example, one magnetic field sensing element 810. Although only one magnetic field sensing element 810 is shown in FIG. 8, it will be appreciated that more than one magnetic field sensing element can be provided per current sensor.

The example current sensor 800 includes three pins in this embodiment, including a VCC (supply voltage) pin 801, a VOUT (output signal) pin 802, and a GND (ground) pin 803. The VCC pin 801 is used for the input power supply or supply voltage for the current sensor 800. A bypass capacitor, C_{BYPASS}, can be coupled between the VCC pin 801 and ground. The VCC pin 801 can also be used for programming the current sensor 800. The VOUT pin 802 may be used for providing the output signal for the current sensor 800 and can also be used for programming. An output load capacitance CL may be coupled between the VOUT pin 802 and ground. The example current sensor 800 can include a first diode D1 coupled between the VCC pin 801 and the regulator 820, a second diode D2 coupled between the chassis ground and the first diode D1, and a third diode D3 coupled between the VOUT pin 802 and chassis ground.

The magnetic field signal generated by the magnetic field sensing element 810 may be input to a dynamic offset cancellation circuit 812, which may be output to an amplifier 814. The amplifier 814 may be coupled to receive the magnetic field signal from the magnetic field sensing element 810 and generate an amplified signal for coupling to the signal recovery circuit 816. Dynamic offset cancellation circuit 812 may take various forms, including chopping circuitry, and may function in conjunction with the offset control 834 to remove offset that can be associated with the magnetic field sensing element 810 and/or the amplifier 814. For example, the offset cancellation circuit 812 can include switches configurable to drive the magnetic field sensing element 810 (e.g., Hall plate) in two or more different directions such that selected drive and signal contact pairs may be interchanged during each phase of the chopping clock signal and offset voltages of the different driving arrangements tend to cancel. A regulator 820 is coupled between a supply voltage VCC and ground and to the various components and sub-circuits of the current sensor 800 to regulate the voltage supplied thereto.

A programming control circuit 822 is coupled between the VCC pin 801 and the EEPROM and control logic 830 to provide appropriate control to the EEPROM and control logic circuit 830. A charge pump pulse generator 826 uses a switching device to control the connection of the supply voltage (VCC) across a load through a capacitor, and thereby generates pulses. The EEPROM and control logic circuit 830 may determine any application-specific coding and can be erased and reprogrammed using a pulsed voltage, for example as provided by the charge pump pulse generator circuit 826. A sensitivity control circuit 824 can be coupled to the amplifier 814. The sensitivity control circuit 824 can generate and provide a sensitivity control signal to the amplifier 814 to adjust a sensitivity and/or operating voltage of the amplifier 814. The output of the amplifier 814 is coupled to the input of the signal recovery circuit 816. An active temperature compensation circuit 832 can be coupled to the sensitivity control circuit 824, the EEPROM and control logic circuit 830, and the offset control circuit 834. The offset control circuit 834 can generate and provide an offset signal to a push/pull driver circuit 818 (which may be an amplifier) to adjust the sensitivity and/or operating voltage of the driver circuit 818. The active temperature compensation circuit 832 can acquire temperature data from the EEPROM and control logic circuit 830 via the temperature sensor 815 and perform necessary calculations to compensate for changes in temperature, if needed. Output clamps circuit 836 is coupled between the EEPROM and control logic 830 and the push/pull driver 818. The output clamps circuit 836 can be used to limit the output voltage and may often be used for diagnostics. For example, if the total output range can be from 0V to 5V, for magnetic field from 0G to 1000G, it may be desired to use a clamp at 0.5V for any field below 100G. For example, it may be known that below 100G, the IC does not return a trustable signal. Hence, if the IC output is 0.5V, it is evident that the measurement is not valid and cannot be trusted. Or clamps at 1V and 4V could be used and the 0-1V and 4-5V range is used for passing diagnostic information: 4.5V on the output could mean “Hall plate is dead” and 0.5V could mean “Undervoltage VCC detected”, etc. The current sensor 810 can also include a broken ground detection circuit 840 coupled between the input VCC 801 and the chassis ground, to indicate when a broken ground connection has been detected.

The output terminal (VOUT pin 802) can be coupled to a system controller and provide a magnetic field signal indicative of a detected magnetic field to the controller for processing.

It will be appreciated that FIG. 8 shows an example current sensor primarily as a digital implementation. However, any appropriate current sensor can be used in accordance with the present disclosure, including both digital and analog implementations.

Now referring to FIG. 9, a current sensor 904 and conductor 902 are shown. The current sensor 904 may include at least two spaced magnetic field sensing elements 905 and a controller circuit 936. The magnetic field sensing elements 905 may be or form a bridge, such as a Wheatstone bridge. A controller circuit 936 can generate various control signals to control processing the output signals of the magnetic field sensing elements 905 in order to thereby provide a current sensor output signal 928 indicative of a level of current through the conductor 902. It should be appreciated that the output signals of the magnetic field sensing elements can be proportional to the current carried by the conductor 902 and that the proportionality constant can be indicative of the distance between the respective magnetic field sensing elements and the conductor 902.

An input/output circuit (I/O) 938 coupled to the controller 936 can control communication between the current sensor 904 and various external devices or systems, such as an Engine Control Unit (ECU) in an automotive application. For example, in some embodiments, the I/O circuit 938 may include a clock (SCL) pin to receive a clock signal and a data (SDA) pin to receive and/or send a data signal. The current sensor 904 may include a power module 940 to power circuitry within the sensor. For example, the power module 940 may include a regulator configured to receive power from a battery.

The current sensor 904 may be positioned proximate to conductor 902 to sense a magnetic field generated by a current through conductor 902. To this end, the current sensor 904 includes the magnetic field sensing elements 905 responsive to receive a driver signal 907 from a bridge driver 906. According to one aspect, the magnetic field sensing elements 905 may include four magnetoresistance elements coupled in a bridge configuration, such as a Wheatstone bridge. For example, magnetoresistance elements may be coupled such that each leg of the bridge includes two magnetoresistance elements positioned adjacent to one another, with one such leg spaced from the other leg. For example, magnetoresistance elements may be coupled such that each leg of the bridge includes two magnetoresistance elements positioned diagonal from each other to form each respective leg of the bridge or group of elements (e.g., element in left leg upper position and element in right leg lower position form a first bridge leg and element in left leg lower position and element in right leg upper position form a second bridge).

With this arrangement, a differential output signal of the bridge (taken between intermediate nodes of each bridge leg) may result in a differential signal that rejects stray fields from sources other than the current through the conductor 902. For example, one bridge leg can provide a first sensing element and the other bridge leg can provide second sensing element so that the resulting differential signal is indicative of the difference between the magnetic field sensed by each bridge leg. The magnetoresistance elements 905 may include at least one of an Indium Antimonide (InSb) element, a giant magnetoresistance (GMR) element, an anisotropic magnetoresistance (AMR) element, a tunneling magnetoresistance (TMR) element or a magnetic tunnel junction (MTJ) element. It should be appreciated that, in some embodiments, magnetic field sensing elements 905 may be provided as one or more Hall effect elements.

The controller circuit 936 can include or be coupled to a bridge trim circuit 908 configured to improve the accuracy of the current sensor output signal 928 by trimming the sensing elements of the bridge 905. For example, in the presence of a reference magnetic field (as may be applied during production), the bridge trim circuit 908 can provide a trim signal 909 to the magnetic field sensing elements 905 to trim the elements of the bridge to ensure that the sensitivity of the individual elements and/or legs of the bridge is matched.

The magnetic field sensing elements 905 can generate a differential magnetic field signal for coupling to a first differential amplifier 910. One or more outputs of first amplifier 910 are coupled to one or more inputs of an H bridge circuit 912. The H bridge circuit 912 can include multiple field effect transistors coupled together to compare two input signals and remove or reduce noise and/or interference (e.g., DC offset) and in some embodiments, apply a gain to the difference between the two input signals.

A compensation coil 914 can be positioned proximate to the magnetic field sensing elements 905 in order to apply an equal and opposite field to the sensing elements 905 and drive the differential field on the bridge to zero Gauss. The current through the coil 914 necessary to bring the differential field on the sensing elements 905 to zero is sensed by a resistor 916 in order to thereby implement a closed-loop current sensing system. It should be appreciated that although the current sensor 904 is shown to be a closed-loop sensor in FIG. 9 in some embodiments, the current sensor 904 can be an open loop sensor.

A voltage on the sense resistor 916 may be coupled to further amplifiers 918 and 920 to implement offset and gain adjustment, including temperature compensation. An output terminal 928 of current sensor 904 (e.g., VOUT) can be provided at the output of the amplifier 920 to provide a signal having a level indicative of the current through the conductor 902.

A comparator 922 can be provided to implement a fault detection feature. To this end, a logic gate 924 has a first input coupled to the output of comparator 922 and a second input coupled to an interrupt signal 925. In some embodiments, logic gate 924 may include an OR gate. An output of logic gate 924 is coupled to a control input of a transistor 926 such that detection of a current greater than a predetermined level causes a fault signal 930 to be provided. The current sensor 904 can include an analog-to-digital converter (ADC) 934 that can be configured to monitor analog signals within the current sensor 904 (e.g., analog references).

The detailed description set forth above, in connection with the appended drawings, is intended as a description of various configurations and is not intended to represent the only configurations in which the concepts described herein may be practiced. The detailed description includes specific details for providing a thorough understanding of the various concepts. It will be apparent to those skilled in the art, however, that these concepts may be practiced without these specific details. In some instances, well-known structures and components are shown in block diagram form in order to avoid obscuring such concepts.

As used herein, the terms “processor” and “controller” are used to describe elements that perform a function, an operation, or a sequence of operations. The function, operation, or sequence of operations can be hard coded into an electronic circuit or soft coded by way of instructions held in a memory device. The function, operation, or sequence of operations can be performed using digital values or using analog signals. In some embodiments, the processor or controller can be embodied in an application specific integrated circuit (ASIC), which can be an analog ASIC or a digital ASIC, in a microprocessor with associated program memory, in a discrete electronic circuit which can be analog or digital, and/or in special purpose logic circuitry (e.g., a field programmable gate array (FPGA)). Processing can be implemented in hardware, software, or a combination of the two. Processing can be implemented using computer programs executed on programmable computers/machines that include one or more processors, a storage medium or other article of manufacture that is readable by the processor (including volatile and non-volatile memory and/or storage elements), at least one input device and one or more output devices. Program code can be applied to data entered using an input device to perform processing and to generate output information. A processor or controller can contain internal processors or modules that perform portions of the function, operation, or sequence of operations. Similarly, a module can contain internal processors or internal modules that perform portions of the function, operation, or sequence of operations of the module.

While electronic circuits shown in figures herein may be shown in the form of analog blocks or digital blocks, it will be understood that the analog blocks can be replaced by digital blocks that perform the same or similar functions and the digital blocks can be replaced by analog blocks that perform the same or similar functions. Analog-to-digital or digital-to-analog conversions may not be explicitly shown in the figures but should be understood.

As used herein, the term “magnetic field sensor” or simply “sensor” is used to describe a circuit that uses one or more magnetic field sensing elements, generally in combination with other circuits. The magnetic field sensor can be, for example, a rotation detector, a movement detector, or a proximity detector. A rotation detector (or movement detector) can sense passing target objects, for example, magnetic domains of a ring magnet or a ferromagnetic target (e.g., gear teeth) where the magnetic field sensor is used in combination with a back-bias or other magnet and can determine target movement speed. Ferromagnetic objects described herein can have a variety of forms, including, but not limited to, a ring magnet having one or more pole pair, and a gear having two or more gear teeth. Ferromagnetic gears are used in some examples below to show a rotating ferromagnetic object having ferromagnetic features, i.e., teeth. However, in other embodiments, the gear can be replaced with a ring magnet having at least one pole pair. Also, linear arrangements of ferromagnetic objects are possible that move linearly.

As used herein, the term “magnetic field sensing element” is used to describe a variety of electronic elements that can sense a magnetic field. The magnetic field sensing element can be, but is not limited to, a Hall effect element, a magnetoresistance element, a magnetotransistor, or an inductive coil. As is known, there are different types of Hall effect elements, for example, a planar Hall element, a vertical Hall element, and a Circular Vertical Hall (CVH) element. As is also known, there are different types of magnetoresistance elements, for example, a semiconductor magnetoresistance element such as Indium Antimonide (InSb), a giant magnetoresistance (GMR) element, for example, a spin valve, an anisotropic magnetoresistance element (AMR), a tunneling magnetoresistance (TMR) element, and a magnetic tunnel junction (MTJ). The magnetic field sensing element may be a single element or, alternatively, may include two or more magnetic field sensing elements arranged in various configurations, e.g., a half bridge or full (Wheatstone) bridge. Depending on the device type and other application requirements, the magnetic field sensing element may be a device made of a type IV semiconductor material such as Silicon (Si) or Germanium (Ge), or a type III-V semiconductor material like Gallium-Arsenide (GaAs) or an Indium compound, e.g., Indium-Antimonide (InSb).

As is known, some of the above-described magnetic field sensing elements tend to have an axis of maximum sensitivity parallel to a substrate or in the plane of the substrate that supports the magnetic field sensing element, and others of the above-described magnetic field sensing elements tend to have an axis of maximum sensitivity perpendicular to a substrate that supports the magnetic field sensing element. In particular, planar Hall elements tend to have axes of maximum sensitivity perpendicular to a substrate, while metal based or metallic magnetoresistance elements (e.g., GMR, TMR, AMR) and vertical Hall elements tend to have axes of maximum sensitivity parallel to a substrate.

As used herein, the term “magnetic field signal” is used to describe any signal that results from a magnetic field experienced by a magnetic field sensing element.

It should be understood that a so-called “comparator” can be comprised of an analog comparator having a two-state output signal indicative of an input signal being above or below a threshold level (or indicative of one input signal being above or below another input signal). However, the comparator can also be comprised of a digital circuit having an output signal with at least two states indicative of an input signal being above or below a threshold level (or indicative of one input signal being above or below another input signal), respectively, or a digital value above or below a digital threshold value (or another digital value), respectively.

It is noted that various connections and positional relationships (e.g., over, below, adjacent, etc.) may be used to describe elements and components in the description and drawings. These connections and/or positional relationships, unless specified otherwise, can be direct or indirect, and the described concepts, systems, devices, structures, and techniques are not intended to be limiting in this respect. Accordingly, a coupling of entities can refer to either a direct or an indirect coupling, and a positional relationship between entities can be a direct or indirect positional relationship.

Also, the following definitions and abbreviations are to be used for the interpretation of the claims and the specification. The terms “comprise,” “comprises,” “comprising, “include,” “includes,” “including,” “has,” “having,” “contains” or “containing,” or any other variation are intended to cover a non-exclusive inclusion. For example, an apparatus, a method, a composition, a mixture, or an article, that includes a list of elements is not necessarily limited to only those elements but can include other elements not expressly listed or inherent to such apparatus, method, composition, mixture, or article.

References in the specification to “embodiments,” “one embodiment, “an embodiment,” “an example embodiment,” “an example,” “an instance,” “an aspect,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it may affect such feature, structure, or characteristic in other embodiments whether explicitly described or not.

Use of ordinal terms such as “first,” “second,” “third,” etc., in the claims to modify a claim element does not by itself connote any priority, precedence, or order of one claim element over another, or a temporal order in which acts of a method are performed, but are used merely as labels to distinguish one claim element having a certain name from another element having a same name (but for use of the ordinal term) to distinguish the claim elements.

In the foregoing detailed description, various features of embodiments are grouped together in one or more individual embodiments for the purpose of streamlining the disclosure. This method of disclosure is not to be interpreted as reflecting an intention that the claims require more features than are expressly recited therein. Rather, inventive aspects may lie in less than all features of each disclosed embodiment.

Elements of different embodiments described herein may be combined to form other embodiments not specifically set forth above. Various elements, which are described in the context of a single embodiment, may also be provided separately or in any suitable subcombination. Other embodiments not specifically described herein are also within the scope of the following claims.

Having described implementations which serve to illustrate various concepts, structures, and techniques which are the subject of this disclosure, it will now become apparent to those of ordinary skill in the art that other implementations incorporating these concepts, structures, and techniques may be used. Accordingly, it is submitted that that scope of the patent should not be limited to the described implementations but rather should be limited only by the spirit and scope of the following claims.

What is claimed is:

1. A current sensing system comprising:
a first semiconductor die supporting a first magnetic field sensing element, the first magnetic field sensing element configured to sense a first magnetic field associated with a first current through a first conductor and a second magnetic field associated with a second current through a second conductor, the first magnetic field sensing element further configured to generate a first output signal indicative of the first current and second current, wherein the first magnetic field sensing element is disposed a first distance from the first conductor and a second distance from the second conductor;
a second semiconductor die supporting a second magnetic field sensing element, the second magnetic field sensing element configured to sense the first magnetic field and the second magnetic field, the second magnetic field sensing element further configured to generate a second output signal indicative of the first current and second current, wherein the second magnetic field sensing element is disposed a third distance substantially equal to the first distance from the second conductor and a fourth distance substantially equal to the second distance from the first conductor; and
a circuit responsive to the first output signal from the first magnetic field sensing element and the second output signal from the second magnetic field sensing element, the circuit configured to generate a current sensor output signal based on a difference between the first output signal and the second output signal.

2. The current sensing system of claim 1 wherein the current sensor output signal is indicative of a difference between the first current and the second current.

3. The current sensing system of claim 1 wherein the first conductor and the second conductor comprise busbars.

4. The current sensing system of claim 1 further comprising a substrate adjacent to the first magnetic field sensing element and the second magnetic field sensing element.

5. The current sensing system of claim 4 wherein the substrate is a printed circuit board (PCB).

6. The current sensing system of claim 5 wherein the first conductor and the second conductor comprise conductive traces.

7. The current sensing system of claim 4 wherein the substrate is a lead frame.

8. The current sensing system of claim 1 wherein the first current flows in an opposite direction from the second current.

9. The current sensing system of claim 1 wherein the circuit comprises a differential operational amplifier.

10. The current sensing system of claim 1 further comprising a first compensation coil proximate to the first magnetic field sensing element and a second compensation coil proximate to the second magnetic field sensing element.

11. The current sensing system of claim 10 wherein the first compensation coil is located in the first semiconductor die and the second compensation coil is located in the second semiconductor die.

12. The current sensing system of claim 10 wherein the first compensation coil and the second compensation coil are located on a substrate supporting the first semiconductor die and the second compensation coil.

13. The current sensing system of claim 1 wherein the first and second magnetic field sensing elements comprise one or more magnetoresistive elements or Hall effect elements.

14. The current sensing system of claim 1 wherein the first conductor is disposed vertically to the second conductor and symmetrically to first magnetic field sensing element and the second magnetic field sensing element.

15. The current sensing system of claim 1 wherein the first conductor is disposed horizontally to the second conductor.

16. A method of sensing a current through one or more conductors, the method comprising:
providing a first semiconductor die supporting a first magnetic field sensing element, the first magnetic field sensing element configured to sense a first magnetic field associated with a first current through a first conductor and a second magnetic field associated with a second current through a second conductor, the first magnetic field sensing element further configured to generate a first output signal indicative of the first current and second current,
positioning the first magnetic field sensing element a first distance from the first conductor and a second distance from the second conductor;
providing a second semiconductor die supporting a second magnetic field sensing element, the second magnetic field sensing element configured to sense the first magnetic field and the second magnetic field, the second magnetic field sensing element further configured to generate a second output signal indicative of the first current and second current;
positioning the second magnetic field sensing element a third distance substantially equal to the first distance from the second conductor and a fourth distance substantially equal to the second distance from the first conductor; and
providing a circuit responsive to the first output signal from the first magnetic field sensing element and the second output signal from the second magnetic field sensing element, the circuit configured to generate a current sensor output signal based on a difference between the first output signal and the second output signal.

17. The method of claim 16 wherein the current sensor output signal is indicative of a difference between the first current and the second current.

18. The method of claim 16 wherein the first conductor and the second conductor comprise busbars.

19. The method of claim 16 further comprising providing a substrate adjacent to the first magnetic field sensing element and the second magnetic field sensing element.

20. The method of claim 19 wherein the substrate is a printed circuit board (PCB).

21. The method of claim 20 wherein the first conductor and the second conductor comprise conductive traces.

22. The method of claim 19 wherein the substrate is a lead frame.

23. The method of claim 16 wherein the first current flows in an opposite direction from the second current.

24. The method of claim 16 wherein the circuit comprises a differential operational amplifier.

25. The method of claim 16 further comprising providing a first compensation coil proximate to the first magnetic field sensing element and a second compensation coil proximate to the second magnetic field sensing element.

26. The method of claim 25 wherein the first compensation coil is located in the first semiconductor die and the second compensation coil is located in the second semiconductor die.

27. The method of claim 25 wherein the first compensation coil and the second compensation coil are located on a substrate supporting the first semiconductor die and the second compensation coil.

28. The method of claim 16 wherein the first and second magnetic field sensing elements comprise one or more magnetoresistive elements or Hall effect elements.

29. The method of claim 16 wherein the first conductor is disposed vertically to the second conductor and symmetrically to first magnetic sensing element and the second magnetic sensing element.

30. The method of claim 16 wherein the first conductor is disposed horizontally to the second conductor.

31. A current sensing system comprising:
a first semiconductor die supporting a first magnetic field sensing element, the first magnetic field sensing element configured to sense a first magnetic field associated with a current through a conductor and generate a first output signal indicative of the current, wherein the first magnetic field sensing element is disposed a first distance from the conductor;
a first compensation coil proximate to the first magnetic field sensing element;
a second semiconductor die supporting a second magnetic field sensing element, the second magnetic field sensing element configured to sense a second magnetic field associated with the current through the conductor and generate a second output signal indicative of the current, wherein the second magnetic field sensing element is disposed a second distance from the conductor equal to the first distance;
a second compensation coil proximate to the second magnetic field sensing element; and
a circuit responsive to the first output signal from the first magnetic field sensing element and the second output signal from the second magnetic field sensing element, the circuit configured to generate a current sensor output signal based on a difference between the first output signal and the second output signal.

32. The current sensing system of claim 31 further comprising a substrate adjacent to the first magnetic field sensing element and the second magnetic field sensing element.

33. The current sensing system of claim 32 wherein the substrate is a printed circuit board (PCB).

34. The current sensing system of claim 32 wherein the substrate is a lead frame.

35. The current sensing system of claim 31 wherein the first compensation coil is located in the first semiconductor die and the second compensation coil is located in the second semiconductor die.

36. The current sensing system of claim 31 wherein the first compensation coil and the second compensation coil are located on a substrate supporting the first semiconductor die and the second compensation coil.

37. The current sensing system of claim 31 wherein the first and second magnetic field sensing elements comprise one or more magnetoresistive elements or Hall effect elements.
